(19) United States
(12) Patent Application Publication
(10) Pub. No.: US 2024/0405171 A1
(43) Pub. Date: Dec. 5, 2024

(54) LIGHT-EMITTING DEVICE, PLANAR LIGHT SOURCE, AND LIQUID CRYSTAL DISPLAY DEVICE

(71) Applicant: NICHIA CORPORATION, Anan-shi (JP)

(72) Inventor: Motokazu YAMADA, Tokushima-shi (JP)

(73) Assignee: NICHIA CORPORATION, Anan-shi (JP)

(21) Appl. No.: 18/663,651

(22) Filed: May 14, 2024

(30) Foreign Application Priority Data
May 30, 2023 (JP) 2023-088534

(51) Int. Cl. H01L 33/50; G02F 1/13357; H01L 33/58

(52) U.S. Cl. CPC H01L 33/507; G02F 1/133603; H01L 33/58; G02F 1/133605

(57) ABSTRACT

A light-emitting device includes: a light-emitting element configured to emit first light; a light-transmissive member covering an upper surface of the light-emitting element and including a wavelength conversion material configured to absorb a portion of the first light and emit second light; a light-scattering member disposed on the light-transmissive member, including a light-scattering material, and having a higher reflectance at a peak wavelength of the first light than at a peak wavelength of the second light; and a light-adjustment member located in or on the light-scattering member and having either (i) a higher absorptance at the peak wavelength of the second light than at the peak wavelength of the first light, or (ii) a higher reflectance at the peak wavelength of the second light than at the peak wavelength of the first light. A lateral surface of the light-transmissive member is exposed from the light-scattering member and the light-adjustment member.

### CROSS-REFERENCE TO RELATED APPLICATIONS

This application is based on and claims priority to Japanese Patent Application No. 2023-088534, filed on May 30, 2023, the entire contents of which are incorporated herein by reference.

### TECHNICAL FIELD

The present disclosure relates to a light-emitting device, a planar light source, and a liquid crystal display device.

### BACKGROUND

A light-emitting device including a light-emitting element, a wavelength conversion layer and a light-adjusting layer is known. In one such light-emitting device, the light-adjusting layer surrounds the lateral surfaces of a light-emitting element, and has a first composition or a second composition (see Japanese Patent Publication No. 2018-29179, for example).

### SUMMARY

It is an object of embodiments of the present disclosure to reduce color unevenness in a light-emitting device.

A light-emitting device according to one embodiment of the present disclosure includes a light-emitting element configured to emit first light; a light-transmissive member covering an upper surface of the light-emitting element, and including a wavelength conversion material configured to absorb a portion of the first light and emit second light; a light-scattering member disposed on the light-transmissive member, including a light-scattering material, and having a higher reflectance at a peak wavelength of the first light than a reflectance at a peak wavelength of the second light; and a light-adjustment member provided in the light-scattering member or on the light-scattering member, and having a higher absorptance or a higher reflectance at the peak wavelength of the second light than an absorptance or a reflectance at the peak wavelength of the first light. A lateral surface of the light-transmissive member is exposed from the light-scattering member and the light-adjustment member.

### BRIEF DESCRIPTION OF THE DRAWINGS

Other objects and further features of the present invention will be apparent from the following detailed description when read in conjunction with the accompanying drawings, in which: FIG. 1 is a schematic top view illustrating a light-emitting device according to a first embodiment;

FIG. 2 is a schematic cross-sectional view of the light-emitting device taken along line II-II of FIG. 1;

FIG. 3 is a schematic top view of the light-emitting device of FIG. 1, from which a first light-transmissive member, a second light-transmissive member, and a light-adjustment member are removed;

FIG. 4 is a schematic top view illustrating leads of the light-emitting device of FIG. 1;

FIG. 5 is a schematic bottom view of the light-emitting device of FIG. 1;

FIG. 6 is a schematic cross-sectional view illustrating a light-emitting device according to a second embodiment;

FIG. 7 is a schematic cross-sectional view illustrating a light-emitting device according to a modification of the second embodiment;

FIG. 8 is a schematic cross-sectional view illustrating a light-emitting device according to a third embodiment;

FIG. 9 is a schematic cross-sectional view (part 1) illustrating another example of a light-emitting device;

FIG. 10 is a schematic cross-sectional view (part 2) illustrating another example of a light-emitting device;

FIG. 11 is a schematic cross-sectional view (part 3) illustrating another example of a light-emitting device;

FIG. 12 is a schematic top view illustrating a planar light source according to the first embodiment;

FIG. 13 is a schematic cross-sectional view of the planar light source taken along line XIII-XIII of FIG. 12;

FIG. 14 is a schematic partial cross-sectional view illustrating the planar light source including partition members; and

FIG. 15 is a configuration diagram illustrating a liquid crystal display device according to a fourth embodiment.

### DETAILED DESCRIPTION

In the following, embodiments of the present disclosure will be described with reference to the accompanying drawings. In the following description, terms indicating specific directions and positions (for example, “upper”, “upward”, “lower”, “downward”, and other terms related to these terms) are used as necessary. These terms are used to facilitate understanding of the present invention with reference to the drawings, and the technical scope of the present invention is not limited by the meaning of these terms. The same reference numerals appearing in a plurality of drawings refer to the same or similar portions or members.

Further, the following embodiments exemplify light-emitting devices and the like to embody the technical idea of the present invention, and the present invention is not limited to the following description. In addition, unless otherwise specified, the dimensions, materials, shapes, relative arrangements, and the like of components described below are not intended to limit the scope of the present invention thereto, but are described as examples. The contents described in one embodiment can be applied to other embodiments and modifications. The sizes, positional relationships, and the like of members illustrated in the drawings may be exaggerated for clearer illustration. Furthermore, in order to avoid excessive complication of the drawings, a schematic view in which some elements are not illustrated may be used, or an end view illustrating only a cut surface may be used as a cross-sectional view.

### First Embodiment

### (Light-Emitting Device 20)

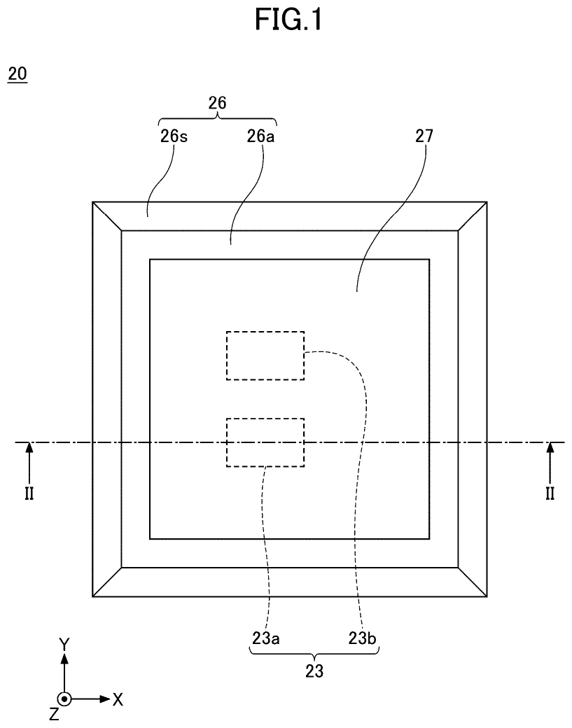

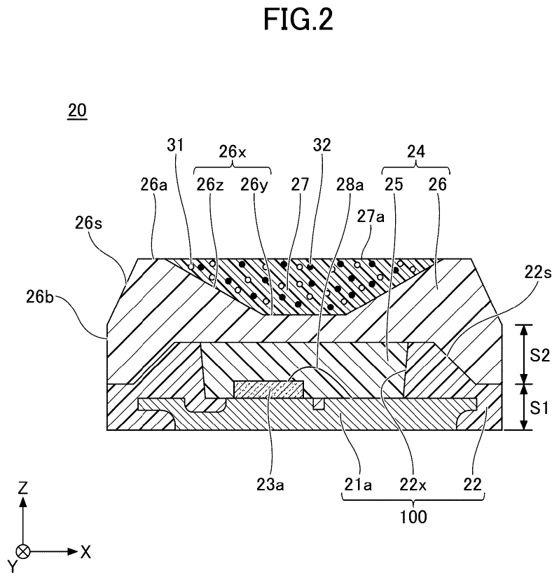

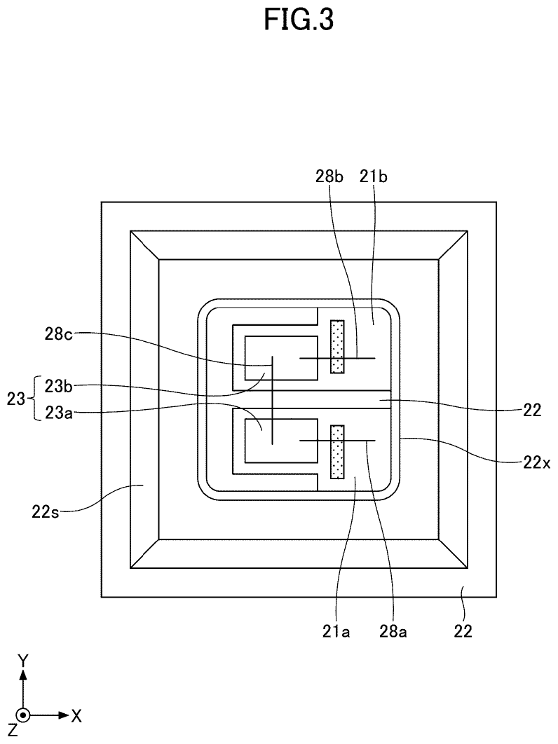

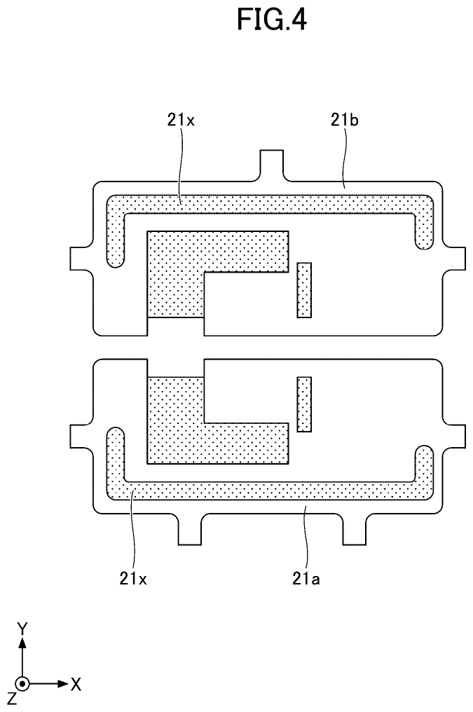

FIG. 1 is a schematic top view illustrating a light-emitting device according to a first embodiment. FIG. 2 is a schematic cross-sectional view of the light-emitting device taken along line II-II of FIG. 1. FIG. 3 is a schematic top view of the light-emitting device of FIG. 1, from which a first light-transmissive member, a second light-transmissive member, and a light-adjustment member are removed. FIG. 4 is a schematic top view illustrating leads of the light-emitting device of FIG. 1. FIG. 5 is a schematic bottom view of the light-emitting device of FIG. 1. The X direction and/or the Y direction illustrated in the drawings may be referred to as a lateral direction, and the Z direction may be referred to as an upward/downward direction, and the direction from the −Z side toward the +Z side may be referred to as an upward direction.

As illustrated in FIG. 1 through FIG. 5, a light-emitting device 20 includes a light-emitting element 23, a light-transmissive member 24, a light-scattering member 27, and a light-adjustment member 32.

The light-emitting element 23 is configured to emit first light. The light-transmissive member 24 covers the upper surface of the light-emitting element 23 and includes a wavelength conversion material configured to absorb a portion of the first light and emit second light. The peak wavelength of the second light is longer than the peak wavelength of the first light. The light-scattering member 27 is disposed on the light-transmissive member 24. The light-scattering member 27 includes a light-scattering material 31 and has a higher reflectance at the peak wavelength of the first light than a reflectance at the peak wavelength of the second light. The light-adjustment member 32 is provided in the light-scattering member 27. The light-adjustment member 32 has a higher absorptance at the peak wavelength of the second light than an absorptance at the peak wavelength of the first light. The lateral surfaces of the light-transmissive member 24 are exposed from the light-scattering member 27 and the light-adjustment member 32.

In the light-emitting device 20, portions of the first light and of the second light are incident on the light-scattering member 27, and mixed light of the first light and the second light is emitted as third light from an upper surface 27a of the light-scattering member 27 to the outside of the light-emitting device 20.

In the light-emitting device 20, the lateral surfaces of the light-transmissive member 24 are exposed from the light-scattering member 27 and the light-adjustment member 32. Thus, the amount of light emitted from the light-emitting device 20 in the lateral direction tends to be large. That is, in the light-emitting device 20, portions of the first light and of the second light are not incident on the light-scattering member 27, and mixed light of the first light and the second light is emitted, as fourth light, laterally and obliquely upward from the lateral surfaces of the light-transmissive member 24. Further, a portion of light, traveling upward and obliquely upward from the light-emitting element 23 and scattered by the light-scattering material 31, is emitted, as a portion of the fourth light, laterally and obliquely upward from the lateral surfaces of the light-transmissive member 24 via the lateral surfaces of the light-scattering member 27 (in the example illustrated in FIG. 2, the surfaces facing inner lateral surfaces 26z of a second light-transmissive member 26 described later). If a portion of the upper surface of the light-transmissive member 24 is exposed from the light-scattering member 27 and the light-adjustment member 32, the fourth light is also emitted from the upper surface of the light-transmissive member 24.

As described, in the light-emitting device 20, the light-scattering member 27 including the light-scattering material 31 is disposed on the light-transmissive member 24, and the lateral surface(s) of the light-transmissive member 24 are exposed from the light-scattering member 27 and the light-adjustment member 32. Accordingly, a portion of the light incident on the light-scattering member 27 can be transmitted through the light-scattering member 27 in the optical axis direction of the light-emitting device 20 (that is, in the Z direction), and the other portion of the light can be scattered by the light-scattering member 27 and emitted laterally and obliquely upward from the lateral surfaces of the light-transmissive member 24. As a result, assuming that the optical axis of the light-emitting device 20 is 0°, it is possible to obtain, for the third light and the fourth light emitted from the light-emitting device 20, a batwing-type emission intensity distribution in which the emission intensity is higher, than at 0°, at angles where the absolute value of the light distribution angle is larger than 0°.

Further, in the light-emitting device 20, the light-adjustment member 32 having a higher absorptance at the peak wavelength of the second light than an absorptance at the peak wavelength of the first light is provided in the light-scattering member 27. Accordingly, in the light-emitting device 20, the chromaticity of the third light can be made close to the chromaticity of the fourth light, and color unevenness of the light-emitting device 20 can be reduced. This will be described in detail below.

In light-emitting devices, in a case where a light-emitting element emits first light, a wavelength conversion material absorbs a portion of the first light and emits second light, and the first light and the second light are incident on a light-scattering member including a light-scattering material, third light in which the first light and the second light are mixed is transmitted through the light-scattering member and is emitted to the outside of the light-emitting device. However, when the diameter of the light-scattering material is d [nm], Rayleigh scattering occurs if the light-scattering material is irradiated with light having a wavelength λ [nm] that satisfies a relationship of 1>πd/λ.

The light-emitting device also emits, in addition to the third light that is transmitted through the light-scattering member and emitted to the outside of the light-emitting device, fourth light that is emitted laterally and obliquely upward to the outside of the light-emitting device without passing through the light-scattering member. Because the fourth light is not affected by Rayleigh scattering, the fourth light can obtain a desired chromaticity. However, the third light obtains a chromaticity different from the chromaticity of the fourth light. This is because, when the light-scattering material is irradiated with the first light and the second light, the first light on the shorter wavelength side is scattered more, and the chromaticity of the third light emitted from the light-scattering member is shifted to the longer wavelength side. As a result, a chromaticity difference occurs between the third light and the fourth light, and color unevenness occurs. For example, if the first light is blue light, the second light is yellow light, and white light is intended to be obtained as the third light and the fourth light, the third light becomes yellowish white light because shorter-wavelength components are reduced by Rayleigh scattering, and the fourth light becomes non-yellowish white light, thereby likely causing color unevenness.

In view of the above, in the light-emitting device 20 according to the embodiment, the light-adjustment member 32 having a higher absorptance at the peak wavelength of the second light than an absorptance at the peak wavelength of the first light is provided in the light-scattering member 27 as described above. Therefore, among the first light and the second light incident on the light-scattering member 27, the second light on the longer wavelength side can be more absorbed than the first light by the light-adjustment member 32. As a result, the chromaticity of the third light can be made close to the chromaticity of the fourth light, and color unevenness of the light-emitting device 20 can be reduced. For example, if the first light is blue light and the second light is yellow light, the third light and the fourth light become white light having similar chromaticities. Thus, color unevenness of the light-emitting device 20 can be reduced.

The difference between the chromaticity of the third light emitted from the light-scattering member 27 and the chromaticity of the fourth light emitted from the lateral surfaces of the light-transmissive member 24 is preferably 10/1,000 or less. Accordingly, the chromaticity of the third light can be made sufficiently close to the chromaticity of the fourth light. Thus, color unevenness of the light-emitting device 20 can be sufficiently reduced.

Referring back to FIG. 1 through FIG. 5, in the example illustrated in FIG. 1 through FIG. 5, the light-emitting device 20 further includes leads 21a and 21b, a resin member 22, light-emitting elements 23a and 23b, and wires 28a, 28b, and 28c. The light-emitting elements 23a and 23b are disposed on the leads 21a and 21b.

Portions of the upper surfaces of the leads 21a and 21b are exposed to the bottom surface of a recessed portion 22x defined by the resin member 22. The leads 21a and 21b, located on the lower surface side of the light-emitting device 20, are exposed from the resin member 22. The light-emitting element 23a is disposed on a portion of the lead 21a located inward of the inner lateral surface of the resin member 22. The light-emitting element 23b is disposed on a portion of the lead 21b located inward of the inner lateral surface of the resin member 22. The wire 28a connects the upper surface of the lead 21a and the upper surface of the light-emitting element 23a. The wire 28b connects the upper surface of the lead 21b and the upper surface of the light-emitting element 23b. The wire 28c connects the upper surface of the light-emitting element 23a and the upper surface of the light-emitting element 23b. The light-emitting elements 23a and 23b are connected in series via the wires 28a, 28b, and 28c.

The light-transmissive member 24 can be constituted by a first light-transmissive member 25 and the second light-transmissive member 26. For example, the first light-transmissive member 25 is located in the recessed portion 22x of the resin member 22. For example, the first light-transmissive member 25 covers the upper surfaces of the light-emitting elements 23a and 23b. For example, the upper surface of the first light-transmissive member 25 is located on the same plane as the upper surface of the resin member 22. For example, the second light-transmissive member 26 covers the upper surface of the resin member 22 including an inclined surface 22s, and covers the upper surface of the first light-transmissive member 25.

An upper surface 26a of the second light-transmissive member 26 may or does not have to be a flat surface. In the example illustrated in FIG. 2, the upper surface 26a of the second light-transmissive member 26 has a recessed portion 26x located above the light-emitting elements 23a and 23b and opening on the upper surface 26a side. The light-scattering member 27 is disposed in the recessed portion 26x. If the light-scattering member 27 includes a resin, the light-scattering member 27 can be disposed in the recessed portion 26x by using, for example, a dropping method. The recessed portion 26x of the second light-transmissive member 26 is defined by a bottom surface 26y and the inner lateral surfaces 26z inclined with respect to the bottom surface 26y.

By providing the upper surface 26a of the second light-transmissive member 26 with the recessed portion 26x and disposing the light-scattering member 27 in the recessed portion 26x, the thickness of the light-emitting device 20 can be reduced. Further, the thickness of the light-scattering member 27 at the center of the recessed portion 26x can be increased, and the thickness of the light-scattering member 27 can be decreased toward the outer periphery of the recessed portion 26x. Thus, the light transmittance at the center of the light-scattering member 27 can be reduced, and the light transmittance can be increased toward the outer periphery of the light-scattering member 27. Therefore, the batwing-type emission intensity distribution can be easily obtained.

The shape of the recessed portion that opens at the upper surface 26a of the second light-transmissive member 26 is not limited to the shape illustrated in FIG. 2. For example, the recessed portion may have a shape without a bottom surface defining a recessed portion, that is, a circular arc shape or a V-shape that protrudes toward the first light-transmissive member 25 in a cross-sectional view. As an example, the light-scattering member 27 covers the entire bottom surface 26y and the inner lateral surfaces 26z. The upper surface 27a of the light-scattering member 27 is, for example, flat. The upper surface 27a of the light-scattering member 27 may have a shape that is recessed toward the bottom surface 26y.

Members included in the light-emitting device 20 will be described in detail below.

### (Leads 21a and 21b)

The lead 21a and the lead 21b are members that are electrically connected to either a negative electrode or a positive electrode of a pair of electrodes of the light-emitting elements 23a and 23b so as to supply electricity to the light-emitting elements 23a and 23b. As the material of the lead 21a and the lead 21b, for example, a metal such as copper, aluminum, gold, silver, iron, nickel, an alloy thereof, phosphor bronze, or iron-containing copper can be used. The lead 21a and the lead 21b can be formed into a predetermined shape by processing such as rolling, punching, extrusion, etching such as wet or dry etching, or a combination thereof. As the material of the lead 21a and the lead 21b, it is preferable to use copper having a high heat dissipation property. The lead 21a and the lead 21b may have a single-layer structure or a layered structure.

In order to improve reflectance, metal plating of silver, aluminum, copper, gold, or the like may be applied in a single-layer or a layered structure to portions or the entirety of the surfaces of the lead 21a and the lead 21b. If a metal layer including silver is formed on the outermost surface of each of the lead 21a and the lead 21b, a protective layer formed of silicon oxide or the like is preferably provided on the surface of the metal layer including silver. Accordingly, the possibility that the metal layer including silver may be discolored by sulfur components or the like in the atmosphere can be reduced. Examples of a method of forming the protective layer include a publicly-known method such as vacuum processing such as sputtering.

As illustrated in FIG. 4, grooves 21x are provided in the upper surfaces of the leads 21a and 21b and this configuration is preferable. The grooves 21x are recessed downward from the upper surfaces of the leads 21a and 21b. The grooves 21x can be formed by etching, pressing, or the like. The grooves 21x may be provided around the light-emitting elements 23a and 23b in a top view, or may be provided in other regions. In the example illustrated in FIG. 3, a portion of the resin member 22 is located in the grooves 21x. Accordingly, the adhesion between the resin member 22 and the leads 21a and 21b can be improved.

As illustrated in FIG. 5, exposing the leads 21a and 21b, located on the lower surface side of the light-emitting device 20, from the resin member 22 allows heat from the light-emitting device 20 to be easily transferred via the leads 21a and 21b to a substrate on which the light-emitting device 20 is mounted. Therefore, the heat dissipation property of light-emitting device 20 can be improved. Further, the lower surfaces of the leads 21a and 21b exposed from the resin member 22 can be used as external terminal portions for electrical connection to the substrate. The light-emitting device 20 may include three or more leads.

### (Resin Member)

The resin member 22 is a member that is located between the lead 21a and the lead 21b and holds the lead 21a and the lead 21b. Portions of the lead 21a and the lead 21b are embedded in the resin member 22. The resin member 22, the lead 21a, and the lead 21b can constitute a resin molded body 100.

The resin molded body 100 has the recessed portion 22x defined by the bottom surface and the inner lateral surfaces, and portions of the bottom surface defining the recessed portion 22x are constituted by the upper surfaces of the lead 21a and the lead 21b. In the example illustrated in FIG. 2, the inner lateral surfaces of the resin member 22 are inclined outward from the upper surfaces of the lead 21a and the lead 21b in the upward direction. Accordingly, lights from the light-emitting elements 23a and 23b are easily reflected upward. The light-emitting elements 23a and 23b are respectively disposed on the upper surfaces of the lead 21a and the lead 21b that define the bottom surface of the recessed portion 22x. The inner lateral surfaces of the resin member 22 may be inclined with respect to the upper surfaces of the lead 21a and the lead 21b, or may be perpendicular to the upper surfaces of the lead 21a and the lead 21b.

In the example illustrated in FIG. 3, the shape of the bottom surface defining the recessed portion 22x is a rectangular shape in a top view. The shape of the upper edges of the lateral surfaces defining the recessed portion 22x has a rectangular shape in a top view. As used herein, the “rectangular shape” includes not only a shape having right-angle corners but also a shape having chamfered corners. The shape having chamfered corners includes a shape in which two orthogonal sides are connected to a curved line, a shape in which two orthogonal sides are connected to a straight line, and the like.

As the material of the resin member 22, a publicly-known material such as a thermosetting resin or a thermoplastic resin can be used. Examples of the thermoplastic resin include a polyphthalamide resin, polybutylene terephthalate (PBT), and an unsaturated polyester. Examples of the thermosetting resin include an epoxy resin, a modified epoxy resin, a silicone resin, and a modified silicone resin. A thermosetting resin such as an epoxy resin or a silicone resin, which has good heat resistance and light resistance, is preferably used as the material of the resin member 22.

The material of the resin member 22 preferably includes a light-scattering material. As the light-scattering material, a material that does not easily absorb light from the light-emitting elements 23a and 23b and has a large difference in refractive index with respect to a resin material is preferably used. Examples of such a light-scattering material include titanium oxide, zinc oxide, silicon oxide, zirconium oxide, aluminum oxide, and aluminum nitride. The content of the light-scattering material with respect to the resin material can be, for example, 10% by weight or more and 90% by weight or less.

As illustrated in FIG. 2, the upper surface of the resin member 22 preferably includes the inclined surface 22s that is inclined outward in the downward direction. With this configuration, a length S1 of a portion of the resin member 22 in the upward/downward direction, which constitutes part of an outer lateral surface of the light-emitting device 20, can be reduced. Thus, a length S2 of an outer lateral surface 26b of the second light-transmissive member 26 in the upward/downward direction can be increased. As a result, a large portion of light emitted from the light-emitting elements 23a and 23b in the lateral direction can be easily extracted from the outer lateral surface 26b to the outside of the light-emitting device 20. Thus, the light extraction efficiency of the light-emitting device 20 can be improved. The inclined surface 22s preferably surrounds the light-emitting elements 23a and 23b in a top view. With this configuration, the light extraction efficiency of the light-emitting device 20 can be further improved. The upper surface of the resin member 22 may be formed as a flat surface without the inclined surface 22s.

### (Light-Emitting Elements 23a and 23b)

The light-emitting elements 23a and 23b are semiconductor elements that emit light in response to the application of voltage. As the light-emitting elements 23a and 23b, publicly-known semiconductor elements formed of nitride semiconductor or the like can be used. Examples of the light-emitting elements 23a and 23b include LED chips. The light-emitting elements 23a and 23b each includes a semiconductor stack. The semiconductor stack includes an n-type semiconductor layer, a p-type semiconductor layer, and a light-emitting layer interposed therebetween. The light-emitting layer may have a structure such as a double heterojunction or a single quantum well (SQW), or may have a structure with a group of light-emitting layers, such as a multiple quantum well (MQW). The peak emission wavelength of the light-emitting layer can be selected as appropriate according to the purpose. The light-emitting layer can be configured to emit visible light or ultraviolet light, for example. Examples of the semiconductor stack including such a light-emitting layer include semiconductors having all compositions obtained by varying the composition ratio x and y within their ranges in the chemical formula InₓAl_{y}Ga_{1-x-y}N (0≤x, 0≤y, x+y≤1).

The semiconductor stack may have a structure including one or more light-emitting layers between an n-type semiconductor layer and a p-type semiconductor layer, or may have a structure in which a structure sequentially including an n-type semiconductor layer, a light-emitting layer, and a p-type semiconductor layer is repeatedly stacked multiple times. If the semiconductor stack includes a plurality of light-emitting layers, the plurality of light-emitting layers may include light-emitting layers having different peak emission wavelengths or may include light-emitting layers having the same peak emission wavelength. The same peak emission wavelength includes a case in which there is a variation within ±10 nm. A combination of peak emission wavelengths of the plurality of light-emitting layers can be selected as appropriate. For example, if the semiconductor stack includes two light-emitting layers, light-emitting layers can be selected in combination of blue light and blue light, green light and green light, red light and red light, ultraviolet light and ultraviolet light, blue light and green light, blue light and red light, or green light and red light. The light-emitting layers may each include a plurality of active layers having different peak emission wavelengths, or may each include a plurality of active layers having the same peak emission wavelength.

In the example illustrated in FIG. 3, the one light-emitting device 20 includes the two light-emitting elements (light-emitting elements 23a and 23b). However, the configuration of the light-emitting device 20 is not limited thereto, and the one light-emitting device 20 may include only one light-emitting element, or may include three or more light-emitting elements. If the one light-emitting device 20 includes a plurality of light-emitting elements, a plurality of light-emitting elements having the same peak emission wavelength may be combined in order to improve the luminous intensity of the entire light-emitting device 20. Further, for example, to improve color reproductivity, a plurality of light-emitting elements having different peak emission wavelengths corresponding to a red color, a green color, and a blue color may be combined. If the light-emitting device 20 includes a plurality of light-emitting elements, all the light-emitting elements may be connected in series, may be connected in parallel, or may be connected in a combination of series connection and parallel connection. The light-emitting elements may be mounted in a face-up manner such that the surface on which the electrodes are formed face upward, or may be mounted in a flip-chip manner such that the surface on which the electrodes are formed face downward.

### (Light-Transmissive Member 24)

The first light-transmissive member 25 and the second light-transmissive member 26 that constitute the light-transmissive member 24 are members having transmissivity to light from the light-emitting element 23.

### [First Light-Transmissive Member 25]

A resin material can be used as the base material of the first light-transmissive member 25, for example. Examples of a resin used as the base material of the first light-transmissive member 25 include publicly-known resins having transmissivity such as a silicone resin and an epoxy resin. Among them, a silicone resin having good reliability (specifically, a phenyl silicone resin, a dimethyl silicone resin, or the like) can be suitably used.

The first light-transmissive member 25 can include a wavelength conversion material. Accordingly, the chromaticity of the light-emitting device 20 can be easily adjusted. The wavelength conversion material included in the first light-transmissive member 25 may be of one type or a plurality of types. The wavelength conversion material included in the first light-transmissive member 25 may be dispersed or locally distributed. As the wavelength conversion material, a publicly-known phosphor can be used. The phosphor is excited by light emitted from the light-emitting element 23, and emits light having a wavelength different from the wavelength of the light emitted from the light-emitting element 23. Examples of the phosphor include yttrium aluminum garnet based phosphors (for example, (Y,Gd)₃(Al,Ga)₅O₁₂:Ce), lutetium aluminum garnet based phosphors (for example, Lu₃(Al,Ga)₅O₁₂:Ce), terbium aluminum garnet based phosphors (for example, Tb₃(Al,Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, CaBMgSi₄O₁₆Cl₂:Eu), silicate based phosphors (for example, (Ba,Sr,Ca,Mg)₂SiO₄:Eu), oxynitride based phosphors such as R-SiAlON based phosphors (for example, (Si,Al)₃(O,N)₄:Eu) and a-SiAlON based phosphors (for example, Ca(Si,Al)₁₂(O,N)₁₆:Eu), nitride based phosphors such as LSN based phosphors (for example, (La,Y)₃Si₆N₁₁:Ce), BSESN based phosphors (for example, (Ba, Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr,Ca)AlSiN₃:Eu), fluoride based phosphors such as KSF based phosphors (for example, K₂SiF₆:Mn), KSAF based phosphors (for example, K₂(Si₁₋ₓAlₓ)F₆-x:Mn, where x satisfies 0<x<1), and MGF based phosphors (for example, 3.5MgO·0.5MgF₂—GeO₂:Mn), quantum dots having a Perovskite structure (for example, (Cs,FA,MA) (Pb,Sn) (F,Cl,Br,I)₃, where FA and MA represent formamidinium and methylammonium, respectively), II-VI quantum dots (for example, CdSe), III-V quantum dots (for example, InP), and quantum dots having a chalcopyrite structure (for example, (Ag,Cu) (In,Ga) (S,Se)₂).

### [Second Light-Transmissive Member 26]

In the example of FIG. 2, the second light-transmissive member 26 covers the upper surface of the first light-transmissive member 25 and the upper surface of the resin member 22 including the inclined surface 22s. Accordingly, lights from the light-emitting elements 23a and 23b can be extracted to the outside of the light-emitting device 20 via the second light-transmissive member 26. In the example of FIG. 2, the second light-transmissive member 26 covers the upper surfaces of the light-emitting elements 23a and 23b with the first light-transmissive member 25 interposed therebetween. However, the configuration is not limited thereto, and the second light-transmissive member 26 may contact the upper surfaces of the light-emitting elements 23a and 23b and cover the light-emitting elements 23a and 23b. That is, the light-transmissive member 24 may be constituted by the second light-transmissive member 26 only. If the light-transmissive member 24 is constituted by the second light-transmissive member 26 only, the wavelength conversion material can be provided in a region within the recessed portion 22x.

In the example illustrated in FIG. 2, the second light-transmissive member 26 has the upper surface 26a and the outer lateral surface 26b. The second light-transmissive member 26 preferably has an inclined surface 26s between the upper surface 26a and the outer lateral surface 26b. The inclined surface 26s is connected to the outer edge of the upper surface 26a and is inclined outward from the outer edge of the upper surface 26a in the downward direction. That is, each of the lateral surfaces of the second light-transmissive member 26 preferably includes the inclined surface 26s and the outer lateral surface 26b that is a vertical surface. In this case, for example, in the second light-transmissive member 26, the outer lateral surface 26b is located outward relative to the upper surface 26a in a top view, and the inclined surface 26s connects the upper end of the outer lateral surface 26b and the outer edge of the upper surface 26a. The lateral surfaces of the second light-transmissive member 26 include the inclined surfaces 26s, and thus light from the light-emitting elements 23a and 23b can be easily extracted to the outside. The outer lateral surface 26b and the inclined surface 26s are also the lateral surfaces of the light-transmissive member 24.

In the second light-transmissive member 26 having the shape described above, the outer lateral surface 26b is located below the inclined surface 26s and is located outward relative to the inclined surface 26s in a top view. Thus, a large portion of light emitted from the light-emitting elements 23a and 23b in the lateral direction is more likely hit the outer lateral surface 26b than the inclined surface 26s. Accordingly, a large portion of light emitted from the light-emitting elements 23a and 23b in the lateral direction can be easily extracted from the outer lateral surface 26b to the outside of the light-emitting device 20. Thus, light from the light-emitting elements 23a and 23b of the light-emitting device 20 can be efficiently spread in the lateral direction. In a top view, the inclined surface 26s and the outer lateral surface 26b preferably surround the light-emitting elements 23a and 23b. With this configuration, the light from the light-emitting elements 23a and 23b can be more efficiently spread in the lateral direction.

The surface roughness of the outer lateral surface 26b may be the same as the surface roughness of the inclined surface 26s, or may be greater than the surface roughness of the inclined surface 26s. If the surface roughness of the outer lateral surface 26b is greater than the surface roughness of the inclined surface 26s, the surface area of the outer lateral surface 26b can be increased. Accordingly, light from the light-emitting elements 23a and 23b can be easily extracted from the outer lateral surface 26b to the outside of the light-emitting device 20. A large portion of light emitted from the light-emitting elements 23a and 23b in the lateral direction is likely to hit the outer lateral surface 26b. Therefore, a large portion of light emitted from the light-emitting elements 23a and 23b in the lateral direction can be efficiency spread in the lateral direction.

A resin material can be used as the base material of the second light-transmissive member 26, for example. A thermosetting resin is preferable as a resin used as the base material of the second light-transmissive member 26. Examples of the thermosetting resin include an epoxy resin, a modified epoxy resin, a silicone resin, a modified silicone resin, an acrylate resin, a urethane resin, and a fluorine-based resin. Among them, a silicone resin and a modified silicone resin, which have good heat resistance and light resistance, are preferable. For example, a phenyl silicone resin or a dimethyl silicone resin can be used as the base material of the second light-transmissive member 26. The base material of the second light-transmissive member 26 may be the same material as or a different material from the base material of the first light-transmissive member 25.

The second light-transmissive member 26 may or does not have to include a light-scattering material. Using the second light-transmissive member 26 including the light-scattering material can facilitate adjustment of the light distribution characteristics of the light-emitting device 20. As the light-scattering material, it is preferably to use a material that does not easily absorb light from the light-emitting elements 23a and 23b and has a large difference in refractive index with respect to the base material. Examples of such a light-scattering material include titanium oxide, zinc oxide, silicon oxide, zirconium oxide, aluminum oxide, and aluminum nitride.

In the example illustrated in FIG. 2, the second light-transmissive member 26 does not include any wavelength conversion material.

### (Light-Scattering Member 27 and Light-Scattering Material 31)

The light-scattering member 27 includes the light-scattering material 31. In the example illustrated in FIG. 2, the light-scattering material 31 is dispersed in the light-scattering member 27. The light-scattering member 27 has reflectivity and transmissivity to light emitted from the light-emitting elements 23a and 23b. The light-scattering member 27 has a higher reflectance at the peak wavelength of the first light than at the peak wavelength of the second light. In other words, the light-scattering member 27 has a lower light transmittance at the peak wavelength of the first light than at the peak wavelength of the second light. A portion of light emitted from the upper surface of the light-transmissive member 24 is reflected by the light-scattering material 31, and the other portion of the light is transmitted through the light-scattering member 27. The light-scattering member 27 preferably has a reflectance of 50% or more at the peak wavelength of the first light and a reflectance of 50% or more at the peak wavelength of the second light.

The light-scattering member 27 covers the upper surfaces of the light-emitting elements 23a and 23b with the light-transmissive member 24 interposed therebetween. Accordingly, a portion of light traveling upward from the light-emitting elements 23a and 23b is reflected by the light-scattering material 31, and thus the amount of light emitted from the light-emitting device 20 in the lateral direction tends to be large. In a top view, at least a portion of each of the light-emitting elements 23a and 23b overlaps the light-scattering member 27. In a top view, the entire light-emitting elements 23a and 23b preferably overlap the light-scattering member 27. With such a configuration, a portion of light traveling upward from the light-emitting elements 23a and 23b can be reflected. Accordingly, the amount of light emitted from the light-emitting device 20 in the lateral direction tends to be large.

As the material of the light-scattering material 31, titanium oxide, zinc oxide, silicon oxide, zirconium oxide, aluminum oxide, or aluminum nitride can be used. The content of the light-scattering material 31 with respect to a material constituting the light-scattering member 27 can be 10% by weight or more and 90% by weight or less. If the light-transmissive member 24 includes a light-scattering material, the concentration of the light-scattering material 31 included in the light-scattering member 27 is preferably higher than the concentration of the light-scattering material included in the light-transmissive member 24. The particle size of the light-scattering material 31 is, for example, 150 nm or less. In such a case, Rayleigh scattering tends to occur at the light-scattering material 31, and thus providing the light-adjustment member 32 is of great technical significance.

If a resin material is used as the base material of the light-scattering member 27, a resin material that is the same as or similar to that of the second light-transmissive member 26 can be used. A difference between the linear expansion coefficient of the base material of the light-scattering member 27 and the linear expansion coefficient of the base material of the second light-transmissive member 26 is not limited, and is preferably 30 ppm/° C. or less. Accordingly, the possibility that the light-scattering member 27 may be detached from the second light-transmissive member 26 can be reduced. For example, if a phenyl silicone resin is used as the base material of the second light-transmissive member 26, the phenyl silicone resin can be used as the base material of the light-scattering member 27. The light-scattering member 27 and the second light-transmissive member 26 may be in contact with each other, or a publicly-known adhesive member may be provided between the light-scattering member 27 and the second light-transmissive member 26.

### (Light-Adjustment Member 32)

The light-adjustment member 32 has absorbency or reflectivity with respect to light emitted from the light-emitting elements 23a and 23b. In the example of FIG. 2, the light-adjustment member 32 is a coloring material having a higher absorptance at the peak wavelength of the second light than an absorptance at the peak wavelength of the first light, and is dispersed in the light-scattering member 27. As the coloring material, a pigment or a dye such as CoAl₂O₄(cobalt blue), YInMn (YInMn blue), or Cu phthalocyanine can be used. If a resin is used as the base material of the light-scattering member 27, the light-adjustment member 32 may be a material that does not dissolve in the resin or may be a material that dissolves in the resin. The type and the amount of the coloring material used can be adjusted as appropriate such that the third light has a desired chromaticity.

The light-adjustment member 32 and the light-scattering material 31 are not necessarily dispersed in the light-scattering member 27, and may be locally distributed in the light-scattering member 27 along the thickness direction of the light-scattering member 27 (along the Z direction). If the light-adjustment member 32 and the light-scattering material 31 are locally distributed along the same direction, the light-adjustment member 32 and the light-scattering material 31 may be arranged one above the other in layers, or the light-adjustment member 32 and the light-scattering material 31 may be arranged in a mixed state. For example, the light-adjustment member 32 and the light-scattering material 31 may be locally distributed on the bottom surface 26y side of the second light-transmissive member 26, and the light-scattering material 31 may be provided on the light-adjustment member 32.

In the example illustrated in FIG. 2, if a resin is used as the base material of the light-scattering member 27, a mixture in which the light-scattering material 31 and the light-adjustment member 32 are mixed in an uncured resin can be dropped into the recessed portion 26x of the second light-transmissive member 26, and then cured. Accordingly, the light-scattering member 27 including the light-scattering material 31 and the light-adjustment member 32 can be disposed in the recessed portion 26x of the second light-transmissive member 26.

### Second Embodiment

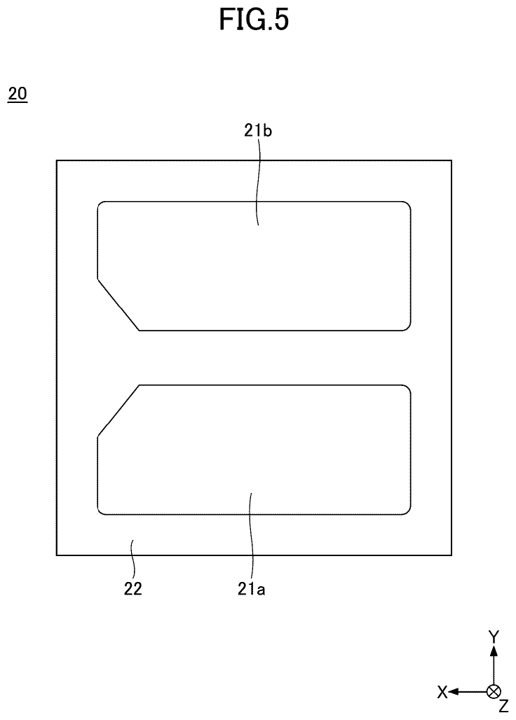

FIG. 6 is a schematic cross-sectional view illustrating a light-emitting device according to a second embodiment. As illustrated in FIG. 6, a light-emitting device 20A differs from the light-emitting device 20 in that a light-adjustment member 32 is provided on a light-scattering member 27. In the example of FIG. 6, the light-adjustment member 32 is included in a sheet 33 disposed on an upper surface 27a of the light-scattering member 27. The light-adjustment member 32 is a coloring material having a higher absorptance at the peak wavelength of the second light than an absorptance at the peak wavelength of the first light. The coloring material described in the first embodiment can be used. In the example illustrated in FIG. 6, the thickness of the sheet 33 is substantially constant. Further, the upper surface of the sheet 33 is flat. The thickness of the sheet 33 is, for example, 200 μm. The material of the sheet 33 may be, for example, a thermosetting resin such as a silicone resin or an epoxy resin.

The light-emitting device 20A includes the light-adjustment member 32. Thus, similar to the first embodiment, color unevenness of the light-emitting device 20A can be reduced.

In the example illustrated in FIG. 6, after the sheet 33 including the light-adjustment member 32 is prepared by being manufactured or purchased, the sheet 33 including the light-adjustment member 32 can be placed on the light-scattering member 27. At this time, the sheet 33 can be bonded to the light-scattering member 27 by using, for example, a light-transmissive adhesive material.

### <Modification of Second Embodiment>

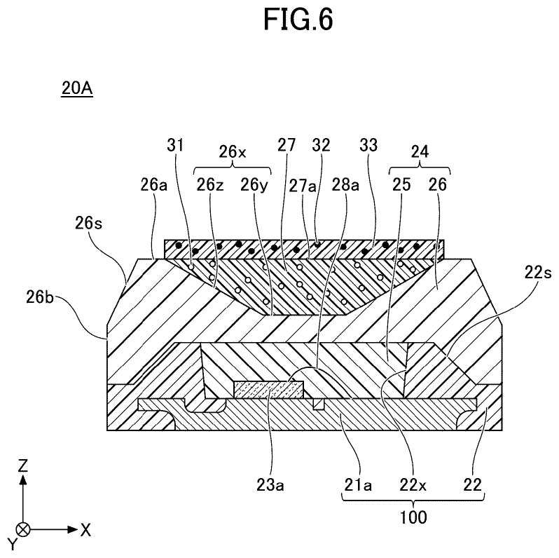

FIG. 7 is a schematic cross-sectional view illustrating a light-emitting device according to a modification of the second embodiment. As illustrated in FIG. 7, a light-emitting device 20B differs from the light-emitting device 20A in that a light-adjustment member 32 is directly provided on the light-scattering member 27 and the light-adjustment member 32 is covered by a covering film 37. The upper surface of the covering film 37 has an uneven shape in a cross-sectional view. In the example of FIG. 7, similar to the example of FIG. 6, the light-adjustment member 32 is a coloring material having a higher absorptance at the peak wavelength of the second light than an absorptance at the peak wavelength of the first light.

The light-emitting device 20B includes the light-adjustment member 32. Thus, similar to the second embodiment, color unevenness of the light-emitting device 20B can be reduced.

In the example illustrated in FIG. 7, light-adjustment members 32 are arranged at regular intervals; however, the configuration of the light-adjustment members 32 is not limited thereto, and the light-adjustment members 32 may be arranged at irregular intervals.

In the example illustrated in FIG. 7, after the light-adjustment members 32 are directly provided on the light-scattering member 27, the covering film 37 is applied by, for example, a spray. In this manner, the light-adjustment members 32 can be covered by the covering film 37. As the covering film 37, for example, a thermosetting resin such as a silicone resin or an epoxy resin can be used. The thickness of the covering film 37 is, for example, 50 μm.

In the example illustrated in FIG. 7, the thickness of the covering film 37 is smaller than the thickness of the light-adjustment members 32 (or if the light-adjustment members 32 are pigments, the thickness of the covering film 37 is smaller than the particle size of the pigments). In this case, the upper surface of the covering film 37 has an uneven shape having projections derived from the light-adjustment members 32. The thickness of the covering film 37 is not necessarily smaller than the thickness of the light-adjustment members 32, and may be the same as or greater than the thickness of the light-adjustment members 32.

### Third Embodiment

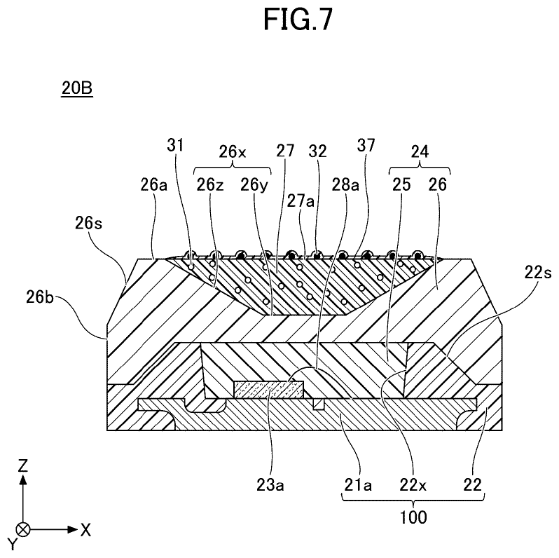

FIG. 8 is a schematic cross-sectional view illustrating a light-emitting device according to a third embodiment. As illustrated in FIG. 8, a light-emitting device 20C differs from the light-emitting device 20 in that a light-adjustment member 35 is provided on the light-scattering member 27. The light-adjustment member 35 is wavelength selective filter such as a dielectric multilayer film having a higher reflectance at the peak wavelength of the second light than a reflectance at the peak wavelength of the first light. The dielectric multilayer film is a multilayer film in which a material having a high refractive index and a material having a low refractive index are alternately stacked in layers. Examples of the dielectric multilayer film include TiO₂/SiO₂, Ta₂O₅/SiO₂, and Nb₂O₅/SiO₂. The thickness of the light-adjustment member 35 is substantially constant.

The light-emitting device 20C includes the light-adjustment member 35. Thus, similar to the first embodiment, color unevenness of the light-emitting device 20C can be reduced. Further, in the light-emitting device 20C, the thickness of the light-adjustment member 35 can be made substantially constant. Thus, chromaticity can be adjusted regardless of the thicknesses of the light-scattering member 27.

### <Variations of Light-Emitting Device>

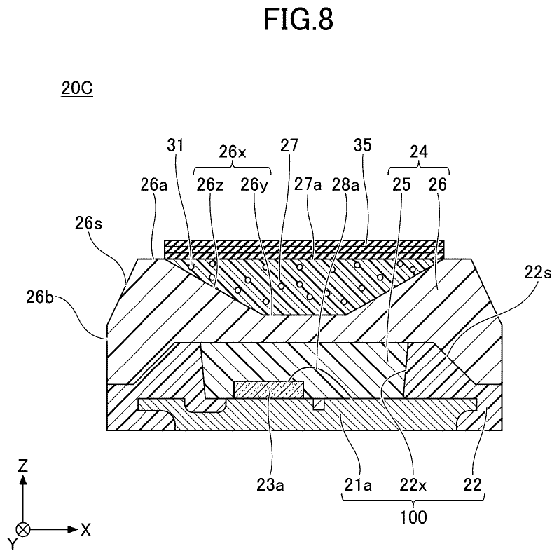

FIG. 9 is a schematic cross-sectional view (part 1) illustrating another example of a light-emitting device. As illustrated in FIG. 9, a light-emitting device 20D includes a light-transmissive member 24A covering the upper surface and the lateral surfaces of a light-emitting element 23. The light-transmissive member 24A is a light-transmissive member including a wavelength conversion material. The light-transmissive member 24A can include, for example, the resin and the wavelength conversion material exemplified in the description of the first light-transmissive member 25.

A pair of conductive members 23t are provided on the lower surface of a light-emitting element 23a. A light reflecting member 41 is provided on the lower surface of the light-transmissive member 24A. The light reflecting member 41 covers the lower surface of the light-emitting element 23, the lateral surfaces of the pair of conductive members 23t, and the lower surface of the light-transmissive member 24A, and exposes the lower surfaces of the pair of conductive members 23t. The lower surfaces of the pair of conductive members 23t, exposed from the lower surface of the light reflecting member 41, are connected to external electrodes 42 provided on the lower surface of the light reflecting member 41. The light reflecting member 41 is preferably a member that reflects light.

A light-scattering member 27 including a light-scattering material 31 is disposed on the light-transmissive member 24A. A light-adjustment member 32 is provided in the light-scattering member 27. The lateral surfaces of the light-transmissive member 24A are exposed from the light-scattering member 27 and the light-adjustment member 32. Similar to the light-emitting device 20, the light-adjustment member 32 is a coloring material having a higher absorptance at the peak wavelength of the second light than an absorptance at the peak wavelength of the first light, and is included in the light-scattering member 27.

The light-emitting device 20D includes the light-adjustment member 32. Thus, similar to the first embodiment, color unevenness of the light-emitting device 20D can be reduced.

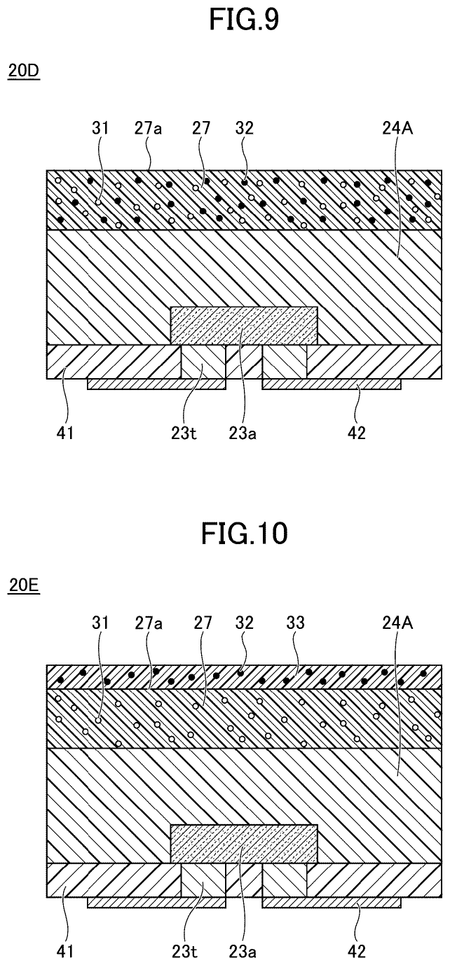

FIG. 10 is a schematic cross-sectional view (part 2) illustrating another example of a light-emitting device. As illustrated in FIG. 10, a light-emitting device 20E differs from the light-emitting device 20D in that a light-adjustment member 32 is provided on a light-scattering member 27. In the example illustrated in FIG. 10, the light-adjustment member 32 is included in a sheet 33 disposed on an upper surface 27a of the light-scattering member 27.

The light-emitting device 20E includes the light-adjustment member 32. Thus, similar to the first embodiment, color unevenness of the light-emitting device 20E can be reduced.

In the light-emitting device 20E, instead of the light-adjustment member 32 and the sheet 33, the light-adjustment member 32 and the covering film 37 illustrated in FIG. 7 may be provided. Further, in the light-emitting device 20E, instead of the light-adjustment member 32 and the sheet 33, the light-adjustment member 35 illustrated in FIG. 8 may be provided. With these configurations as well, color unevenness of the light-emitting device 20E can be reduced.

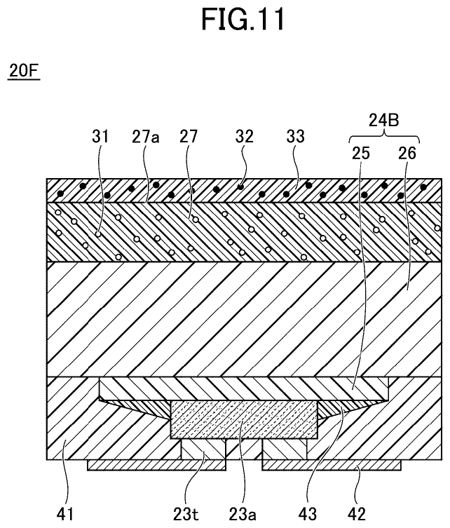

FIG. 11 is a schematic cross-sectional view (part 3) illustrating another example of a light-emitting device. As illustrated in FIG. 11, a light-emitting device 20F includes a light-transmissive member 24B that includes a first light-transmissive member 25 and a second light-transmissive member 26. The first light-transmissive member 25 covers the upper surface of a light-emitting element 23a and extends outward beyond the outer periphery of the upper surface of the light-emitting element 23a in a top view. A light-transmissive part 43 having an inclined surface may be provided such that the light-transmissive part 43 contacts at least a portion of the lateral surfaces of the light-emitting element 23a closer to the upper surface of the light-emitting element 23a, and a portion of the lower surface of the first light-transmissive member 25 extending outward beyond the outer periphery of the light-emitting element 23a. The light-transmissive part 43 can include, for example, the resin exemplified in the description of the first light-transmissive member 25.

The second light-transmissive member 26 covers the upper surface of the first light-transmissive member 25 and extends beyond the outer periphery of the upper surface of the first light-transmissive member 25 in a top view. A pair of conductive members 23t are provided on the lower surface of the light-emitting element 23a. Further, a light reflecting member 41 is provided. The light reflecting member 41 covers the lateral surfaces of the pair of conductive members 23t, the lateral surfaces of the light-emitting element 23a, the lateral surfaces of the first light-transmissive member 25, the inclined surface of the light-transmissive part 43, and the lower surface of the second light-transmissive member 26. The lower surfaces of the pair of the conductive members 23t, exposed from the lower surface of the light reflecting member 41, are connected to external electrodes 42 provided on the lower surface of the light reflecting member 41.

A light-scattering member 27 including a light-scattering material 31 is disposed on the light-transmissive member 24B. Further, a light-adjustment member 32 is provided on the light-scattering member 27. The lateral surfaces of the light-transmissive member 24B are exposed from the light-scattering member 27 and the light-adjustment member 32. In the example illustrated in FIG. 11, the light-adjustment member 32 is included in a sheet 33 disposed on an upper surface 27a of the light-scattering member 27.

Further, in the light-emitting device 20F, the lateral surfaces of the second light-transmissive member 26, the light-scattering member 27, and the sheet 33 can be vertical surfaces. Alternatively, in the light-emitting device 20F, the lateral surfaces of the second light-transmissive member 26, the light-scattering member 27, and the sheet 33 can be inclined surfaces. In the latter case, the batwing-type emission intensity distribution can be easily obtained.

The light-emitting device 20F includes the light-adjustment member 32. Thus, similar to the first embodiment, color unevenness of the light-emitting device 20F can be reduced.

In the light-emitting device 20F, instead of the light-adjustment member 32 and the sheet 33, the light-adjustment member 32 and the covering film 37 illustrated in FIG. 7 may be provided. Further, in the light-emitting device 20F, instead of the light-adjustment member 32 and the sheet 33, the light-adjustment member 35 illustrated in FIG. 8 may be provided. With these configurations as well, color unevenness of the light-emitting device 20F can be reduced.

Further, light-transmissive encapsulation members covering the respective light-emitting devices 20D, 20E, and 20F may be provided. The encapsulation members can have, for example, a substantially hemispherical shape.

### [Planar Light Source 1]

The above-described light-emitting devices can be disposed on a substrate so as to constitute part of a planar light source. In the following, the planar light source will be described by using the light-emitting devices 20 as an example. However, instead of the light-emitting devices 20, any of the above-described light-emitting devices 20A to 20F may be used.

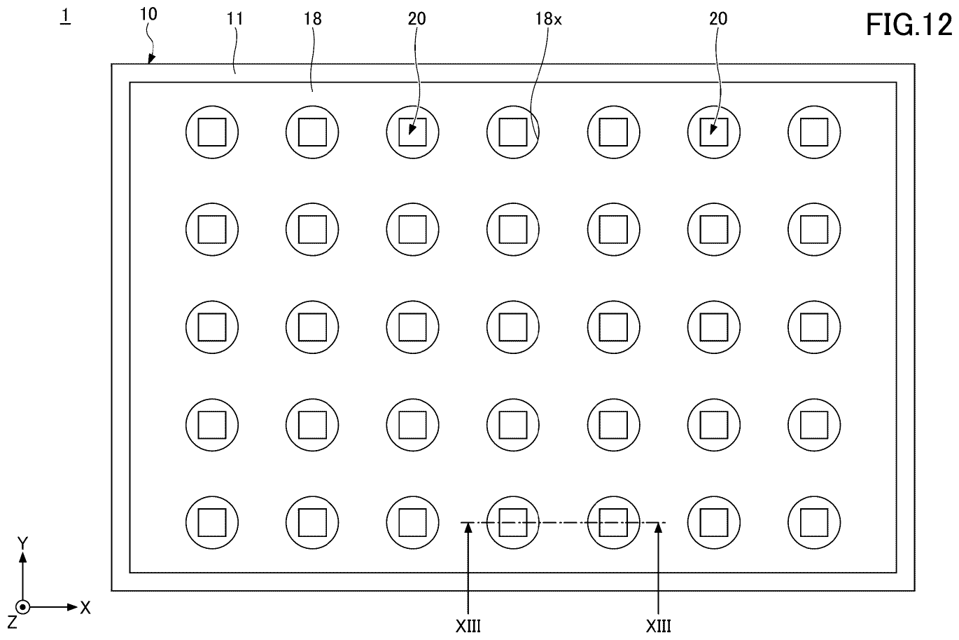

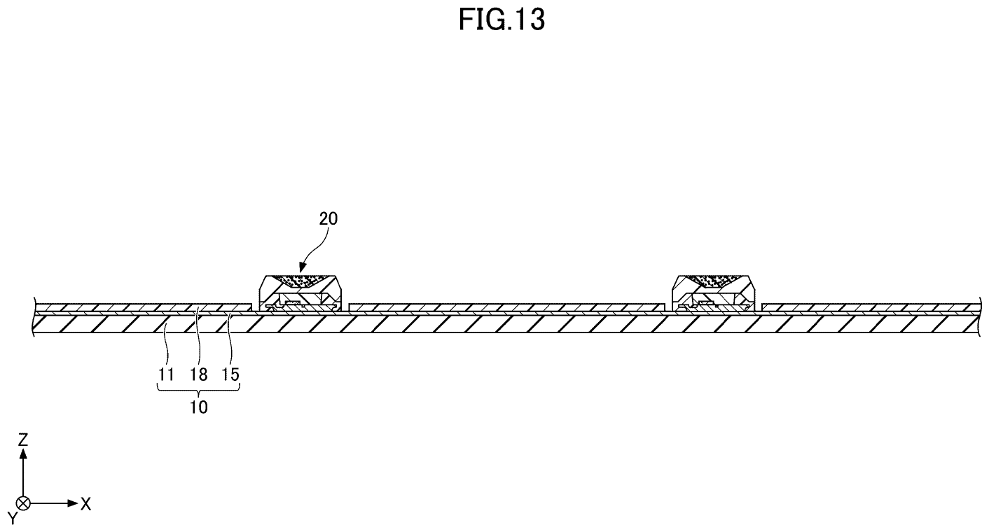

FIG. 12 is a schematic top view illustrating a planar light source according to the first embodiment. FIG. 13 is a schematic cross-sectional view of the planar light source taken along line XIII-XIII of FIG. 12.

Referring to FIG. 12 and FIG. 13, a planar light source 1 includes a substrate 10 and a plurality of light-emitting devices 20 arranged two-dimensionally. In the planar light source 1, the light-emitting devices 20 are arranged on the substrate 10 in a matrix, for example. The planar light source 1 includes the plurality of light-emitting devices 20 in which color unevenness is reduced, and thus color unevenness of the entire the planar light source 1 can be reduced. Members included in the planar light source 1 will be described in detail below.

### (Substrate 10)

The substrate 10 is a member on which the plurality of light-emitting devices 20 are mounted. In the example of FIG. 12 and FIG. 13, the substrate 10 includes a base member 11, conductor wiring 15, and a covering member 18. The conductor wiring 15 is a member for supplying power to the light-emitting devices 20, and is disposed on the upper surface of the base member 11. The covering member 18 covers a portion of a region of the conductor wiring 15 where no electrical contact is made with the light-emitting devices 20. The covering member 18 has openings 18x, and the light-emitting devices 20 are respectively disposed in the openings 18x.

As the material of the base member 11, a material that can at least isolate the conductor wiring 15 can be used, and examples of the material include ceramics, resins, and composite materials. Examples of the resins include a phenol resin, an epoxy resin, a polyimide resin, a BT resin, polyphthalamide (PPA), and polyethylene terephthalate (PET). Examples of the composite materials include a mixture of any one of the above resins and an inorganic filler such as glass fiber, silicon oxide, titanium oxide, aluminum oxide, or the like, a glass fiber reinforced resin (glass epoxy), and a metal substrate in which a metal member is coated by an insulating layer.

The thickness of the base member 11 can be appropriately selected. The base member 11 can be either a flexible substrate that can be manufactured by roll-to-roll processing or a rigid substrate. The rigid substrate may be a bendable thin rigid substrate.

The material of the conductor wiring 15 is not particularly limited as long as a conductive material is used, and a material generally used as a wiring layer of a circuit board or the like can be used. As the material of the conductor wiring 15, copper can be used, for example.

The covering member 18 has an insulating property. Examples of the material of the covering member 18 include the same materials as those exemplified as the material of the base member 11. As the covering member 18, any of the above-described resins including a light-reflective white filler or including a large number of air bubbles can be used. Accordingly, light emitted from the light-emitting devices 20 are reflected by the covering member 18, and thus the light extraction efficiency of the planar light source 1 can be improved.

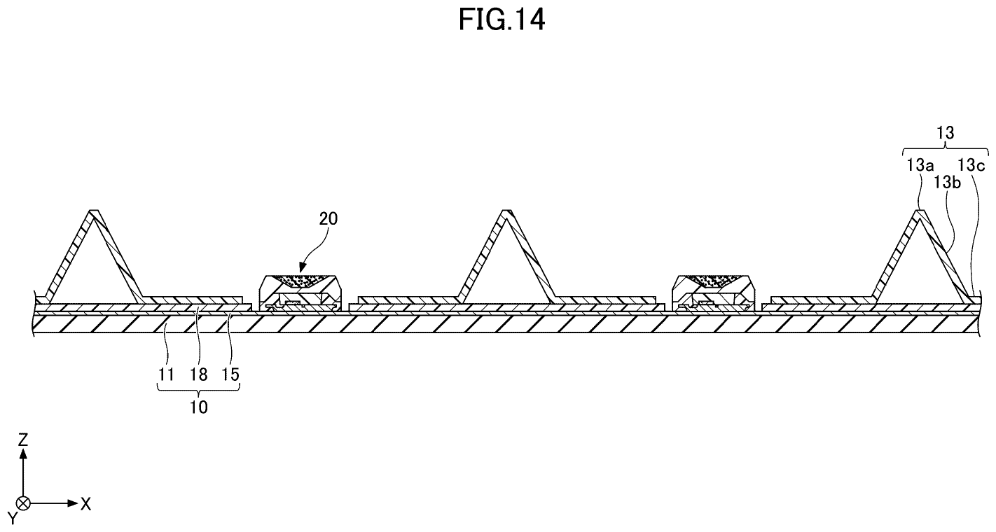

FIG. 14 is a schematic partial cross-sectional view illustrating the planar light source including partition members. As illustrated in FIG. 14, the planar light source 1 can include partition members 13.

The partition members 13 are disposed on the same side of the substrate 10 as the light-emitting devices 20. The partition members 13 include top portions 13a arranged in a grid pattern in a top view, wall portions 13b surrounding the light-emitting devices 20 in a top view, and bottom portions 13c connected to the lower ends of the wall portions 13b. The partition members 13 include a plurality of regions surrounding the light-emitting devices 20. For example, each of the wall portions 13b of the partition members 13 extends from a corresponding top portion 13a toward the substrate 10, and a region that includes the light-emitting device 20 and is surrounded by opposing wall portions 13b becomes narrower toward the substrate 10 in a cross-sectional view. In the example of FIG. 14, one light-emitting device 20 is disposed in one section surrounded by the wall portions 13b. However, two or more light-emitting devices 20 may be disposed in one section.

The partition members 13 preferably have light reflectivity. Accordingly, light emitted from the light-emitting devices 20 can be efficiently reflected upward by the partition members 13. In this case, each of the partition members 13 may be formed by using a resin or the like including a light reflective material such as titanium oxide, aluminum oxide, or silicon oxide, or may be formed by using a resin including no reflective material and then disposing a reflective material on the surface. Alternatively, a resin including a plurality of micro air bubbles may be used. In this case, the interfaces between the air bubbles and the resin reflect light. Examples of the resin used for the partition members 13 include thermoplastic resins such as an acrylic resin, a polycarbonate resin, a cyclic polyolefin resin, polyethylene terephthalate, polyethylene naphthalate, and polyester, and thermosetting resins such as an epoxy resin and a silicone resin. The partition members 13 are preferably set such that the reflectance to light emitted from the light-emitting devices 20 is 70% or more.

In the above-described example, the planar light source 1 including the substrate 10 has been described. However, the configuration of the planar light source 1 is not limited thereto, and the substrate 10 is provided as necessary and can be omitted. For example, the planar light source 1 can have a structure in which the plurality of light-emitting devices 20 are held by a monolithic light-transmissive resin or the like.

The planar light source 1 may include an optical member disposed above the light-emitting devices 20 with the partition members 13 interposed therebetween. The optical member is, for example, a diffusion sheet. Providing the planar light source 1 with the diffusion sheet can improve the uniformity of light extracted from the planar light source 1 to the outside. In addition, the planar light source 1 can further include at least one selected from the group consisting of a first prism sheet, a second prism sheet, and a polarizing sheet above the diffusion sheet. Providing the planar light source 1 with one or more of these optical members can further improve the uniformity of the light.

### Fourth Embodiment

In a fourth embodiment, an example of a liquid crystal display device using the planar light source 1 as a backlight source will be described.

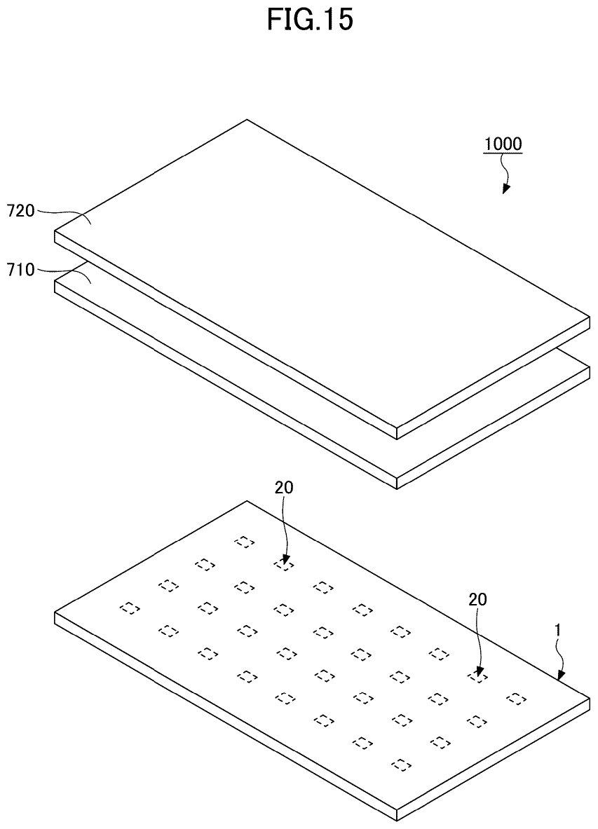

FIG. 15 is a configuration diagram illustrating a liquid crystal display device according to the fourth embodiment. As illustrated in FIG. 15, a liquid crystal display device 1000 includes, from the top, a liquid crystal panel 720, an optical member 710, and the planar light source 1. For example, an optical member in which a diffusion plate, a first prism sheet, a second prism sheet, and a DBEF (reflective polarizing sheet) are stacked in order from the planar light source 1 side can be provided above the light-emitting devices 20 of the planar light source 1.

The liquid crystal display device 1000 is what is known as a direct lit liquid crystal display device in which the planar light source 1 is disposed below the liquid crystal panel 720. In the liquid crystal display device 1000, the liquid crystal panel 720 is irradiated with light emitted from the planar light source 1.

From the viewpoint of thickness reduction in the planar light source 1, the thickness of the planar light source 1 can be 15 mm or less. Accordingly, the thickness of the planar light source 1 can be reduced, thereby reducing the thickness of the liquid crystal display device 1000.

As a backlight of the liquid crystal display device 1000, the planar light source 1 can be used for a television, a tablet, a smartphone, a smartwatch, a head-up display, digital signage, or a bulletin board. Further, the planar light source 1 can be used as a light source for lighting, and can be used for an emergency light, a linear lighting, various types of illumination, an in-vehicle instrument panel, or the like.

According to a light-emitting device of certain embodiments of the present disclosure, color unevenness can be reduced.

Although embodiments have been described in detail above, the above-described embodiments are non-limiting examples, and various modifications and substitutions can be made to the above-described embodiments without departing from the scope described in the claims.

What is claimed is:

1. A light-emitting device comprising:
a light-emitting element configured to emit first light;
a light-transmissive member covering an upper surface of the light-emitting element and comprising a wavelength conversion material configured to absorb a portion of the first light and emit second light;
a light-scattering member disposed on the light-transmissive member, comprising a light-scattering material, and having a higher reflectance at a peak wavelength of the first light than at a peak wavelength of the second light; and
a light-adjustment member located in or on the light-scattering member and having either (i) a higher absorptance at the peak wavelength of the second light than at the peak wavelength of the first light, or (ii) a higher reflectance at the peak wavelength of the second light than at the peak wavelength of the first light,
wherein a lateral surface of the light-transmissive member is exposed from the light-scattering member and the light-adjustment member.

2. The light-emitting device according to claim 1, wherein:
the light-adjustment member is a coloring material having the higher absorptance at the peak wavelength of the second light than at the peak wavelength of the first light, and
the coloring material is dispersed in the light-scattering member.

3. The light-emitting device according to claim 1, wherein:
the light-adjustment member is a coloring material having the higher absorptance at the peak wavelength of the second light than at the peak wavelength of the first light, and
the coloring material is provided on the light-scattering member.

4. The light-emitting device according to claim 1, wherein:
the light-adjustment member is a wavelength selective filter having the higher absorptance at the peak wavelength of the second light than at the peak wavelength of the first light, and
the wavelength selective filter is provided on the light-scattering member.

5. The light-emitting device according to claim 1, wherein:
the light-adjustment member is a dielectric multilayer film having the higher reflectance at the peak wavelength of the second light than at the peak wavelength of the first light, and
the dielectric multilayer film is provided on the light-scattering member.

6. The light-emitting device according to claim 1, wherein:
the light-scattering member has a reflectance of 50% or more and 99% or less at the peak wavelength of the first light, and has a reflectance of 50% or more and 99% or less at the peak wavelength of the second light.

7. The light-emitting device according to claim 1, wherein:
a difference between a chromaticity of light emitted from the light-scattering member and a chromaticity of light emitted from the lateral surface of the light-transmissive member is 10/1,000 or less.

8. The light-emitting device according to claim 1, wherein:
the light-transmissive member comprises:
a first light-transmissive member that covers the upper surface of the light-emitting element and comprises the wavelength conversion material, and
a second light-transmissive member that covers an upper surface of the first light-transmissive member and does not comprise the wavelength conversion material.

9. The light-emitting device according to claim 8, wherein:
an upper surface of the second light-transmissive member has a recessed portion located above the light-emitting element and opening on an upper surface side of the second light-transmissive member, and
the light-scattering member is disposed in the recessed portion.

10. The light-emitting device according to claim 9, wherein:
the recessed portion of the second light-transmissive member is defined by a bottom surface and an inner lateral surface that is inclined with respect to the bottom surface, and
the light-scattering member covers the bottom surface and the inner lateral surface, and has an upper surface having a shape that is recessed toward the bottom surface.

11. The light-emitting device according to claim 8, wherein:
the second light-transmissive member has an inclined surface that is connected to an outer edge of an upper surface of the second light-transmissive member and inclined outward from the outer edge of the upper surface in a downward direction.

12. A planar light source comprising:
a plurality of light-emitting devices of claim 1 arranged two-dimensionally.

13. A liquid crystal display device comprising:
the planar light source of claim 12 for use as a backlight light source.
